(19) United States
(12) Patent Application Publication
(10) Pub. No.: US 2010/0178768 A1
(43) Pub. Date: Jul. 15, 2010

(54) CONTROLLING PASSIVATING FILM PROPERTIES USING COLLOIDAL PARTICLES, POLYELECTROLYTES, AND IONIC ADDITIVES FOR COPPER CHEMICAL MECHANICAL PLANARIZATION

(75) Inventor: Yuzhuo Li, Heidelberg (DE)

Correspondence Address: OBLON, SPIVAK, MCCLELLAND MAIER & NEUSTADT, L.L.P., 1940 DUKE STREET, ALEXANDRIA, VA, 22314, US

(73) Assignee: BASF SE, LUDWIGSHAFEN (DE)

(21) Appl. No.: 12/601,286

(22) PCT Filed: Jun. 13, 2008
(86) PCT No.: PCT/US08/66837

§ 371 Date: Nov. 23, 2009

Related U.S. Application Data
(60) Provisional application No. 60/944,198, filed on Jun. 15, 2007.

(51) Int. Cl. H01L 21/461; C09K 13/00

(52) U.S. Cl. 438/692; 252/79.1; 252/79.2; 257/E21.304

(57) ABSTRACT

The present invention provides for a copper CMP slurry composition which comprises a complexing agent, an oxidizer, an abrasive and a passivating agent. The present invention also provides for a method of chemical mechanical planarization of a copper conductive structure which comprises administering the copper CMP slurry composition during the planarization process.

### INCORPORATION BY REFERENCE

Any foregoing applications and all documents cited therein or during their prosecution (“application cited documents”) and all documents cited or referenced in the application cited documents, and all documents cited or referenced herein (“herein cited documents”), and all documents cited or referenced in herein cited documents, together with any manufacturer's instructions, descriptions, product specifications, and product sheets for any products mentioned herein or in any document incorporated by reference herein, are hereby incorporated herein by reference, and may be employed in the practice of the invention.

### BACKGROUND OF THE INVENTION

Copper Chemical Mechanical Planarization (Cu CMP) is a rapidly growing segment in today's semiconductor devices fabrication process [1]. Copper CMP slurry typically contains an oxidizer that chemically converts the metal film for easy removal, abrasive particles that enhance the abrasiveness of the pad, a complexing agent that enhances the solubility of the abraded metal/metal oxide, a passivating agent that protects the lower lying areas, a pH regulating agent, and surfactant [2].

A proven strategy for copper CMP slurry formulation involves three common stages: 1) selection of an oxidizer-complexing agent pair that significantly softens the copper film; 2) selection of an effective passivating agent that can prevent the film from isotropic dissolution; and 3) introduction of abrasives particles into the above solution. There have been many successful combinations for each stage and overall formulations.

The main function of the passivating agent is to protect the copper film from aggressive chemical attack that may lead to isotropic dissolution of the copper film. Ideally, in the protection of such passivating agent, the copper film in the protruded area is selectively removed by mechanical force thus yielding a step height reduction.

As far as the passivating film is concerned, the native copper oxide structures formed in the presence of strong oxidizer under certain pH conditions can serve the purpose for many applications. However, for CMP purposes, such a hard surface film does not usually lead to any meaningful material removal under the mechanical forces exerted by a polishing pad. In addition, previously known slurries which can give high material removal rates and/or low static etch rates often do not result in high step height reduction efficiency. Therefore, there is a need

### SUMMARY AND OBJECTS OF THE INVENTION

Surprisingly, the problems in the art with regard to copper chemical mechanical planarization were overcome by building a soft passivating layer upon a copper film softened with a complexing agent.

The present invention provides for a copper CMP slurry composition which comprises a complexing agent, an oxidizer, an abrasive and a passivating agent.

The present invention also provides for a method of chemical mechanical planarization of a copper conductive structure which comprises administering the copper CMP slurry composition during the planarization process.

### DETAILED DESCRIPTION OF THE INVENTION

A first aspect of the invention provides for a copper CMP slurry composition which comprises a complexing agent, an oxidizer, an abrasive and a passivating agent.

In one embodiment of the first aspect of the invention, the complexing agent can be but is not limited to glycine, ammonium citrate, ammonium phosphate, ammonium acetate, ammonium thiocyanate, and 2,4-pentadione, and combinations thereof. The slurry of the invention includes about 1% to about 10% of the one or more complexing agents, by weight of the slurry, more preferably about 3% to about 5% by weight of slurry.

In one embodiment of the first aspect of the invention, the oxidizer agent can be but is not limited to hydrogen peroxide, ammonium persulfate, potassium iodate, potassium permanganate, ferric nitrate, and cerium (IV) compounds such as ceric nitrate and ceric ammonium nitrate, bromates, chlorates, chromates, and iodic acid, and mixtures thereof.

In one embodiment of the first aspect of the invention, the abrasive is selected from the group consisting of colloidal particles, polyelectrolytes, an ionic compound and combinations thereof.

The inclusion of an abrasive results in a significant increase in material removal rate (20-1000%), while maintaining or improving the static etch rate (<30 A/min) and improving the step height reduction efficiency (>85%). By optimizing the passivating film thickness and chemical composition, surface defects such as corrosion and pits can be avoided. In another embodiment of the invention, the inclusion of an abrasive results in a significant increase in material removal rate (50-500%), while maintaining or improving the static etch rate (about 1 A/min to <30 A/min) and improving the step height reduction efficiency (>85% to about 99%). In yet another embodiment of the invention, the inclusion of an abrasive results in a significant increase in material removal rate (75-200%), while maintaining or improving the static etch rate (about 5 A/min to <30 A/min) and improving the step height reduction efficiency (>85% to about 95%). In still another embodiment of the invention, the inclusion of an abrasive results in a significant increase in material removal rate (90-110%), while maintaining or improving the static etch rate (about 10 A/min to <30 A/min) and improving the step height reduction efficiency (>85% to about 90%).

The colloidal particles of the first aspect of the invention can be but is not limited to silica, alumina, titania, ceria, zirconia, and diamond. The particles may be organic in nature (polymeric or non-polymeric) or organic/inorganic composite. The particle dimension should be in the range of passivating film thickness which can range from a few nanometers to a few dozens of nanometers. The surface property of the particles should be compatible with the passivating film though static charge attraction, hydrogen bonding, hydrophobic-hydrophobic interaction, and complexation. The concentration of these particles should be high enough to insure the adequate incorporation into the film and low enough not to disturb the function of the passivating film or creating a lubrication effect. In one embodiment of the invention, the concentration should range from 50 ppm to 50,000 of ppm.

The polyelectrolytes of the first aspect of the invention can be but is not limited to polystyrene sulfonate (PSS), poly(acrylic acid) (PAA), Lignosulfonates, Nafion, polyethylene amine, poly(2-acrylamido-2-methyl-1-propanesulfonic acid), naphthalene sulfonate formaldehyde condensate (e.g. Daxad 19—a sodium salt with a mol. wt. of 8000) and polyaniline. The polyelectrolyte may be positively or negatively charged. The dimension of these polyelectrolytes should be in the range of passivating film thickness which can range from a few nanometers to a few dozens of nanometers. The chemical property of these polyelectrolytes should be compatible with the passivating film though static charge attraction, hydrogen bonding, hydrophobic-hydrophobic interaction, and complexation. The concentration of these electrolytes should be high enough to insure the adequate incorporation into the film and low enough not to disturb the function of the passivating film or creating a lubrication effect. In one embodiment of the invention, the concentration should range from 50 to 50,000 ppm.

The ionic species of the first aspect of the invention can be but is not limited to chloride, bromide, iodide, fluoride, isocyanides, acetates, sulfate, and persulfate. The ionic species preferred to be anionic in nature due to the charge of copper surface. In some cases, a positively charged species may be preferred. The ionic species may be added to the slurry deliberately or generated as a by-product on the copper surface through redox reactions or exchange reactions. The concentration of these ionic species should be high enough to insure the adequate incorporation into the film and low enough not to disturb the function of the passivating film. In one embodiment of the invention, concentration should range from 5-5,000 ppm.

It is commonly observed that a passivating agent in a copper CMP slurry will not only lower the static etch rate but also lower the removal rate. As a strong corrosion inhibitor, benzotriazole (BTA) is the most commonly used passivating agent in copper CMP slurry. A vast number of publications and reports have been devoted to the use of BTA in metal CMP slurry [3-16].

Due to the complexity of the CMP slurries, most investigations on the passivation film were conducted with model systems in which some of the key components were absent such as oxidizers, complexing agents, and abrasive particles. It is also generally assumed that the inclusion of these components such as colloidal particles into the actual CMP slurries will not significantly perturb the passivating film. It is our opinion that this is a gross oversight. The addition of colloidal particles into the slurry will have a profound impact on the nature of the passivating film. The optimization of such film can lead to a better performance during copper CMP.

The abrasive particles are often viewed as a simple physical component that enhances the mechanical strength of the pad and slurry. It is our opinion that this is an overly simplistic assumption. The abrasive particles usually have very high surface areas. The particles can serve as an absorbing site for many chemical components including the passivating agent. The surface adsorption phenomenon not only can alter the effective concentration of the passivating agent in solution but also leads to a possible incorporation of these abrasive particles into the passivation film. Furthermore, the abrasive particles may also serve as adsorption sites for small polishing debris particles, which prevent the rapid aggregation of the debris particles and avoid the scratches caused by these large aggregates. In this invention, the roles of these particles are greatly expanded as an active component for the formation of passivation film. Furthermore, the concept of intercalating such particles into passivating film is also extended to other chemical additives such as polyelectrolytes, surfactants, and small ionic species.

The most commonly used passivating agent for this purpose is benzotriazole.

As described earlier, the native copper oxide structures formed in the presence of an oxidizer under certain pH conditions can prevent the free dissolution of copper into copper ions. In addition to such oxide structures, there are at least three other types of layers that can accumulate on the oxidized copper surface to inhibit copper corrosion:
Salt layer
Surfactant layer
Hydrophobic complex stack

It has been reported that some ionic species may accumulate at the surface due to static charge interactions. At high local concentration, the diffusion of these species may be limited hence the dissolution of copper is inhibited. Various phosphate salts are examples of this type.

The second type of corrosion inhibiting film may be built with a passivating agent that is capable of forming a complex with copper. Unlike the complexing agent described earlier, the passivating agent-copper complex does not lead to rapid dissolution of copper ions. Instead, it attracts more passivating agent to adsorb on to the complex and then to the passivating agents themselves. Eventually, a thin film of passivating agent is formed which completely inhibits the copper corrosion. Benzotriazole (BTA) is an excellent example of this type.

The third type of corrosion inhibiting agent (typically surfactant) is attracted to the copper surface by static charges. Unlike the salts, these surfactant molecules tend to stack into monolayer or double layers in accordance to their phase behavior. The focus of this section is on the characteristics and applications of hydrophobic passivating agent.

Many commercial and developmental copper CMP slurries contain benzotriazole (BTA) as a corrosion inhibitor. In representative copper CMP slurry, a combination of hydrogen peroxide (H₂O₂) and a complexing agent is used to oxidize and soften the copper surface. Without any passivating agent, such a solution can give high copper removal regardless of the involvement of any abrasive particles. The material removal using such a solution is, however, mostly isotropic. In another words, the step height reduction efficiency is practically zero when using such a polishing solution due to the fact that the softened copper surface can be significantly disrupted or removed with even the weakest mechanical force including the shear force impinged by the fluid flow.

In the presence of a dedicated passivating agent such as benzotriazole (BTA), the softened film is somewhat protected and hardened. The art of slurry formulation is to balance the need for protection in the lower lying area and the need for removal at higher or protruded areas. More specifically, a proper combination of BTA as passivating agent and a complexing agent can balance the need to have low static etch rate (in the absence of mechanical abrasion) and a high polishing rate (in the presence of mechanical abrasion) [18]. For a CMP solution containing glycine and hydrogen peroxide, addition of BTA results in a significant reduction in the Cu removal rate due to the formation of Cu-BTA complex on the copper surface.

For example, Deshpande et al. showed that BTA acted as corrosion inhibitor and decreased the dissolution rate [19]. They also showed that the inhibition efficiency of BTA was enhanced by an increase in BTA concentration as well as the presence of hydrogen peroxide. This is consistent with the fact that the passivation film has two key components. The first is a complex layer between BTA and oxidized copper. The second is a hydrophobic layer stacked with BTA molecules as shown in FIG. 1.

Steigerwald et al. reported that the Cu-BTA passivation film was almost 20 nm thick after a 10 min immersion in solution at pH 2 [22]. Cohen and coworkers also studied the stoichiometry, thickness, and chemical composition of the Cu-BTA using in-situ ellipsometry and ex-situ x-ray photoelectron spectroscopy [13]. The authors reported that film grown on Cu₂O and bare Cu under oxidizing conditions are in the order of 5-40 Å thick and the chemical composition of this layer is mostly Cu⁺¹-BTA. Walsh et al. suggests that the BTA film is composed of a monolayer that is in direct contact with the copper film and multilayer built on top of the monolayer [6]. They reveal that in the monolayer, BTA molecular plane is oriented within 15° of the surface normal. In the multilayer, the molecular plane is tilted by about 40° from the plane of copper surface.

Notoya et al. showed that BTA exhibited the highest inhibition efficiency at pH 6 [23]. This is consistent with the fact that, to form both complexing and multi-layer effectively, the BTA molecules must be neutral. BTA would not be effective if the molecules are protonated (under acidic condition) or deprotonated (under extreme basic condition).

Besides BTA, a range of other chemicals have also been studied as corrosion inhibitor in copper CMP solution/slurry. Sekar and Ramanathan studied hydrazine as an inhibitor for Cu CMP in nitric acid based slurry [24]. They reported that material removal rate and static etch rate decreased with the addition of hydrazine. They also noticed that the addition of hydrazine to the slurry improves the surface roughness of the polished copper surface. Du et al. used 3-amino-triazol as corrosion inhibitor for copper CMP slurry based on hydrogen peroxide-glycine system [25]. The result from their study showed that the addition of amnio triazol suppresses both static etch rate and material removal rate of copper. In the X-ray Photoelectron Spectroscopy XPS analysis, it was revealed that addition of amino triazol corrosion inhibitor suppresses the oxide formation on the copper surface. It is possible that the surface adsorption of amnio triazol on the copper surface prevents the normal growth of copper oxide.

Hu et al. showed that citric acid could be used as corrosion inhibitor in 3 vol % of HNO₃ solution [26]. It is found that the addition of citric acid reduces the material removal rate and improves the planarization efficiency for copper CMP. Using a potentiodynamic polarization study the authors showed that citric acid inhibits copper corrosion in HNO₃ solution. They suggested that the passivation layer consists of a non-native citrate complex film which inhibits etching. Considering the fact that citric acid is commonly used as a complexing agent that promotes dissolution of copper, the formation of such passivating layer under such a circumstance is unique. Lee reported the inhibiting effect of imidazole on copper corrosion in HNO₃ solution using potentiodynamic study [27]. The imidazole was shown to act as an effective inhibitor to prevent Cu corrosion. Cu-imidazole complex film is simultaneously formed with the Cu oxide in the presence of imidazole which reduces the copper corrosion.

Surfactant is commonly used as a dispersing agent in CMP slurry for abrasive particle stabilization. It is important to point out that the wafer surface is also available for surfactant molecules to adsorb. The net result of such surface adsorption may function as a passivating film. Depending upon the nature and the concentration of surfactant, the adsorption may result in monolayer, double layer, or an array of hemi-micelles. Also depending upon the operating pH of the slurry, the copper surface may be positively or negatively charged. As the isoelectric point of copper oxide surface is about 6, the surface may exhibit slight positive charge in a solution that is below pH 6.

At high pH, the surface may be slightly negatively charged. It is logical to expect that a surfactant with opposite charge to the copper surface should be more effective in serving as a passivating agent due to electrostatic attraction between the surfactant molecule and copper surface. Hong et al. investigated the performance of anionic, cationic, and nonionic surfactant as corrosion inhibitor at various slurry pH [28]. They showed that slurry containing anionic surfactant drastically suppresses the copper etching in the pH range of 2 to 8. For cationic surfactant, the suppression of copper corrosion was effective in the pH range between 2 and 3 and for pH greater than 6. It was concluded that nonionic surfactants did not show significant corrosion inhibiting characteristics in CMP slurry. This is consistent with the charge analysis described above.

We have investigated the use of surfactants as potential corrosion inhibitors which showed that the electrostatic attraction between the charged surfactant molecules and copper surface may not be the only criteria for forming an effective passivation layer. For example, a low concentration of cationic surfactant can also form an effective passivating film on copper surface at a pH where the copper surface is clearly positive such as 3-5 [30]. An answer to such a puzzle can be traced back to the counter ion effect.

More specifically, the counter ion of a surfactant may play a significant role in forming a film on copper surface. For example, the bromide ions in CTAB may bridge the gap between the two positively charged centers on copper surface and cationic surfactant molecule. It is also important to note that the packing density of the surfactant layer could be low in general due to the charge repulsion among surfactant head groups with the same charge. It is easy to understand that when a single surfactant is used, due to charge repulsion, the protection of the metal film by such a surfactant system may be inadequate. When a mixed surfactant system is employed, the charge repulsion among surfactants may be minimized which leads to a better and tighter packed passivating film.

It has previously been shown that a mixed surfactant system containing anionic and cationic surfactant in the molar ratio of 4:1 with total surfactant concentration of 0.058 wt % could reduce the copper static etch rate from over 100 nm/min to less than 10 nm/min for a CMP solution containing 2 wt % H₂O₂ and 1 wt % glycine at pH 5 [31]. The optimum molar ratio between the cationic and anionic surfactants is a function of copper surface charge density which is related to pH and other environmental factors. In general, a greater copper surface charge density should translate to a lower demand on the availability of anionic counter surfactant. Unlike compounds such as BTA, the potential disadvantage for a surfactant based passivating film is its durability against shear flow during polishing. After all, the film (usually mono- or double layer of surfactant molecules) may be too thin to withstand the level of shear force during polishing.

### BRIEF DESCRIPTION OF THE DRAWINGS

The following detailed description, given by way of example, but not intended to limit the invention solely to the specific embodiments described, may best be understood in conjunction with the accompanying drawings, in which:

FIG. 1 is a schematic view of the formation of BTA passivation film on oxidized copper surface.

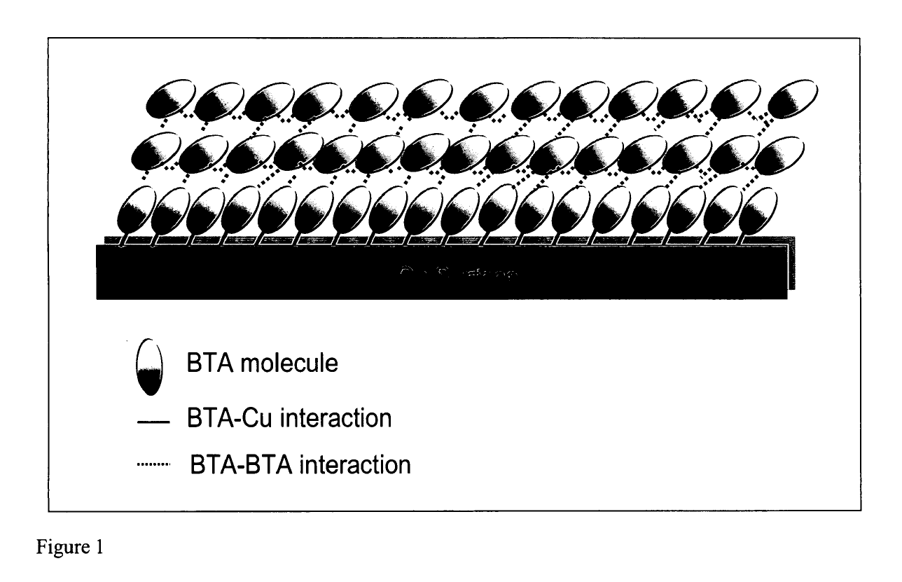

FIG. 2 shows BTA passivating film thickness as a function of concentration of chloride ions.

FIG. 3 shows material removal rates as a function of chloride ion concentration.

FIG. 4 shows the influence of static etch rate on copper surface by chloride ion as a function of BTA concentration.

FIG. 5 shows a representative copper patterned wafer after polishing using a slurry containing chloride ion. The microscope picture shows 5 micron copper lines in an area of 50% metal density.

FIG. 6 shows a static etch rate of copper film as a function of polyelectrolyte.

FIG. 7 shows a BTA passivation film thickness as a function of a polyelectrolyete Daxad 19.

FIG. 8 shows material removal rate of copper film as a function of trace amount of abrasive particles.

FIG. 9 shows a percent BTA adsorption onto copper surface as a function of the amount of colloidal silica present in the slurry. The independency of static etch rate of the copper film in relation to the presence of colloidal silica is also revealed.

FIG. 10 shows a schematic view of the Kaufman Model for step height reduction in which the surface is constantly modified and removed. The removal in the protruded areas are more prominent than those in the trench. A critical requirement is the breakage at the corners. As a result, the step height is reduced and the trench width is kept the same.

FIG. 11 shows a schematic view of the Delamination Model for poor step height reduction in which the surface is constantly modified and removed. The removal in the protruded areas is no more prominent than those in the trench. A critical requirement of corner breakage found in the Kaufman model is not met. As a result, the step height is not reduced and the trench width is slightly widened.

FIG. 12 shows a step height reduction efficiency as a function of material removal rate (MRR) and static etch rate (SER).

FIG. 13 shows thickness and step-heights as a function of time during Cu patterned wafer polishing with abrasive-free surfactant based slurry; Step-height reduction efficiency value of 35% was achieved. Diamond and square data points indicate thickness and step-height values respectively.

FIG. 14 shows thickness and step-heights as a function of time during Cu patterned wafer polishing with abrasive based surfactant slurry; Step-height reduction efficiency value of 95% was achieved. Diamond and square data points indicate thickness and step-height values respectively.

FIG. 15 shows the cross section of a patterned copper wafer is shown. The seed copper layer is usually deposited through vapor method which is denser with greater purity. The electroplated copper tends to contain impurities such as chloride ions. Due to the differences between PVD and EP methods, the removal rate of these two type of coppers are different.

Having thus described in detail various embodiments of the present invention, it is to be understood that the invention defined by the above paragraphs is not to be limited to particular details set forth in the above description as many apparent variations thereof are possible without departing from the spirit or scope of the present invention.

### EXAMPLES

### Example 1

### Standard CMP Solution

Two abrasive free CMP solutions were prepared which contain 1% glycine as complexing agent and 1% hydrogen peroxide as oxidizer. To one solution, 1 mM of BTA was also added as passivating agent. The solutions were adjusted to pH 6, 5, and 4 using hydrochloric acid or nitric acid.

TABLE 1
Static etch rate for an abrasive free CMP solution that contains 1%
glycine as complexing agent and 1% hydrogen peroxide as oxidizer.

| 1% glycine | | | |
|---|---|---|---|
| 1% hydrogen peroxide | | 0.001 mol/L BTA | Without BTA |
| (H₂O₂) | | SER(nm/min) | SER(nm/min) |
| pH | pH = 4.00 | 130 | 120 |
| adjusted by | pH = 5.00 | 96 | 121 |
| HCl | pH = 6.00 | 18 | 135 |
| pH | pH = 4.00 | 38 | 134 |
| adjusted by | pH = 5.00 | 8 | 124 |
| HNO₃ | pH = 6.00 | 7 | 115 |

As shown in Table 1, the static etch rates are almost constant for those solutions without BTA at all pH's. This is due to the fact that, without BTA as passivating agent, the static etch rate is limited by the dissolution power of the complexing agent and the protection of the native copper oxide film which is thin and porous.

The effects of pH and the presence of chloride ions on these two opposite forces are minimal. In the presence of BTA, however, the effect of pH and the presence of chloride ions are much more prominent. More specifically, the lower the pH the greater the static etch rate. This is a direct result of increase solubility of BTA which leads to a thinner and more porous passivating film.

The presence of chloride ion has a profound effect on the static etch rate. This is a strong indication that the presence of chloride ion significantly changed the effectiveness of the BTA passivating film, either thinner or more porous.

### Example 2

### CMP Solution with Sodium Chloride

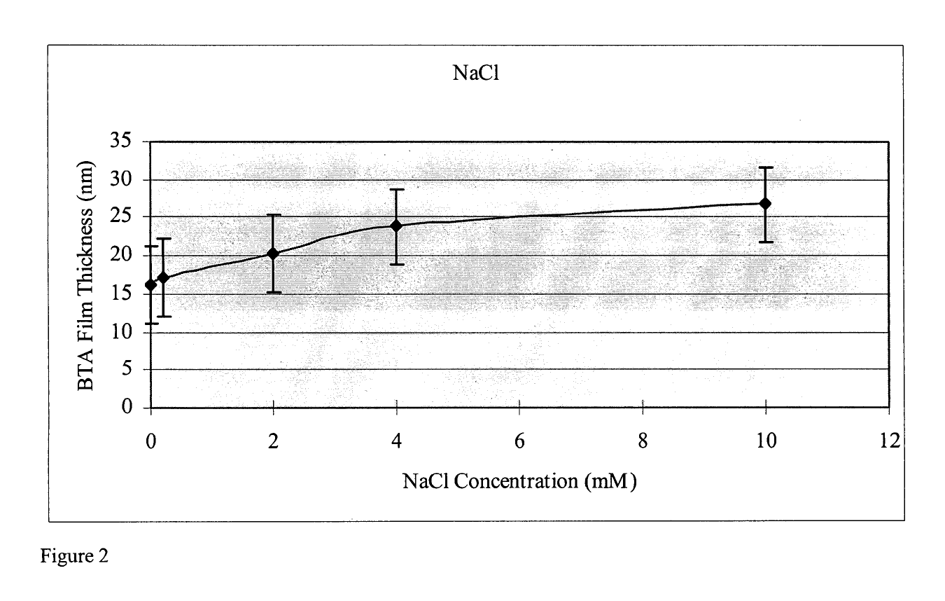

A set of abrasive free solutions as described in Example 1 were prepared. The solution contains various amounts of sodium chloride. The BTA concentration in solution was monitored using an UV/Vis spectrometer for the samples before and after they are exposed to a fixed amount of copper powders. The concentration of BTA decreases due to the surface adsorption phenomenon. Based on the total loss of BTA from solution and the surface area of the copper powders, the thickness of the BTA film formed on the copper surface can be estimated. As shown in FIG. 2, the presence of chloride ions leads to an increase in total thickness of the passivating film.

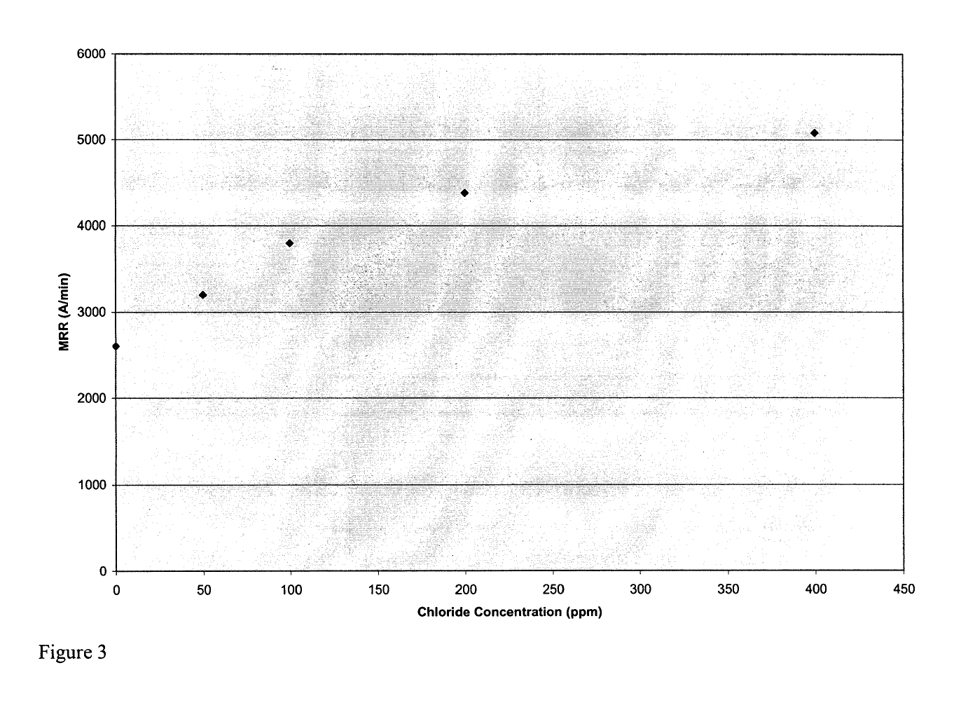

Considering the fact, as described in Example 1, that the chloride ion also leads to an increase in static etch rate, one must conclude that the BTA passivating film in the presence of chloride ions must be more porous and less effective. Such a change in passivation effectiveness can also be clearly illustrated by its increase in material removal rate during polishing (FIG. 3).

### Example 3

### Effect of BTA on Chloride Ions

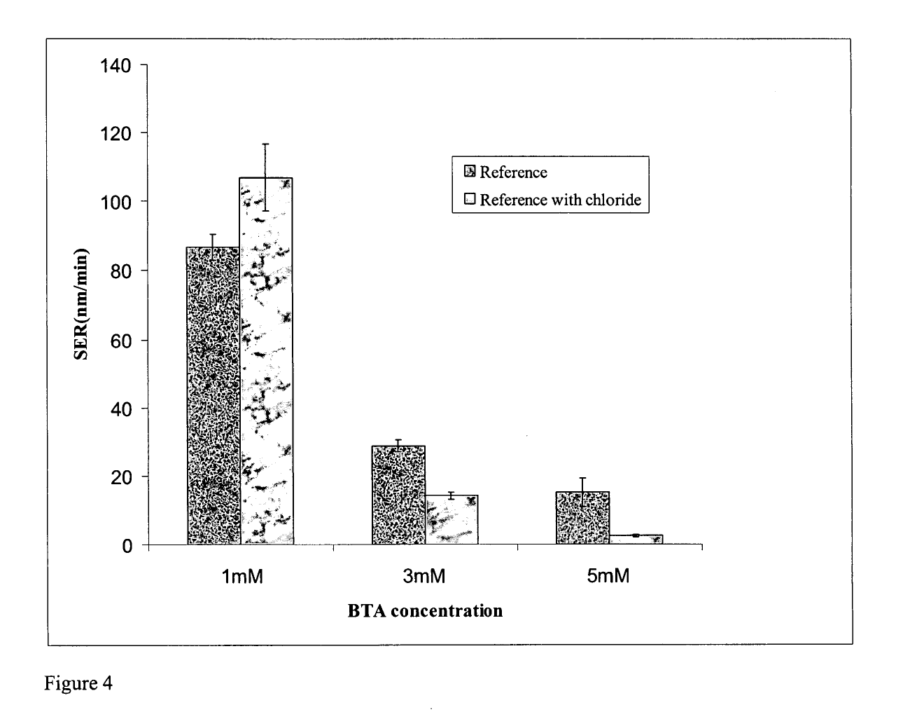

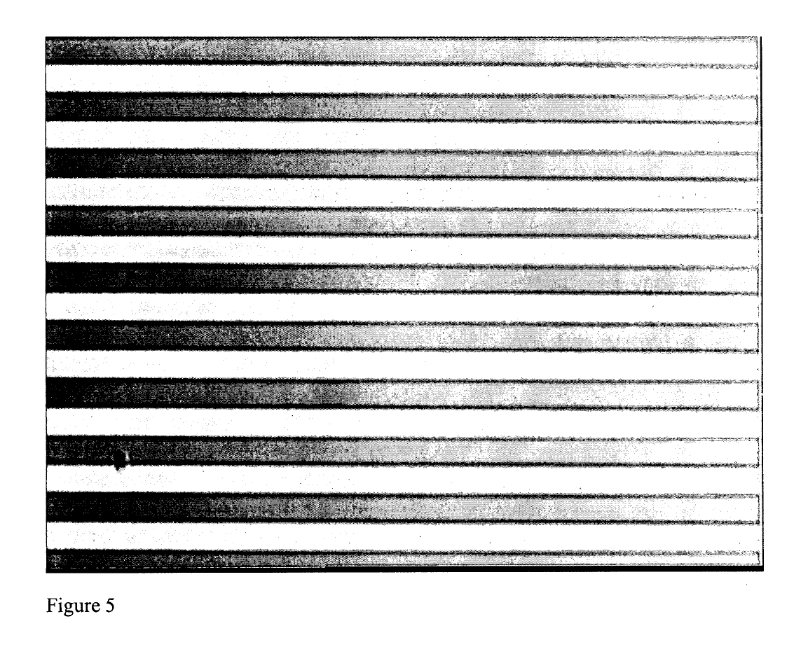

A potential disadvantage of the presence of chloride ions in a copper CMP slurry is its corrosiveness or increase static etch rate. It has been demonstrated that the static etch rate can be controlled by having enough free BTA in the solution. More specifically, as shown in FIG. 4, at high concentration of BTA the static etch rate actually decreases in the presence of chloride. A set of polishing experiments were carried out using slurries containing chloride ions. As shown in FIG. 5, there is no sign of corrosion spots on the polished patterned wafers using a slurry that contains chloride ions.

### Example 4

### CMP Solution with Anionic Polyelectrolyte

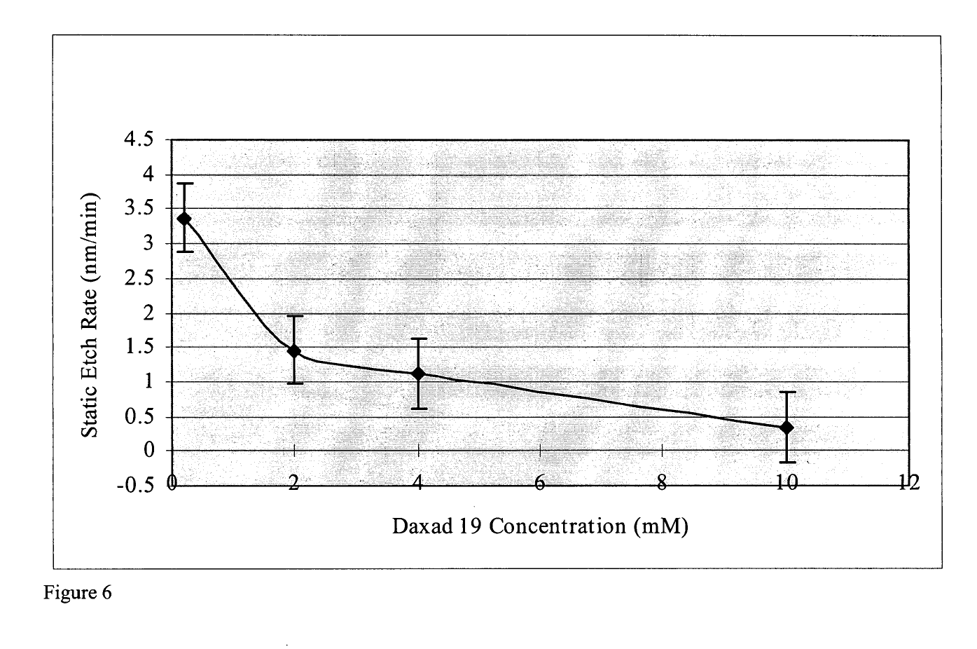

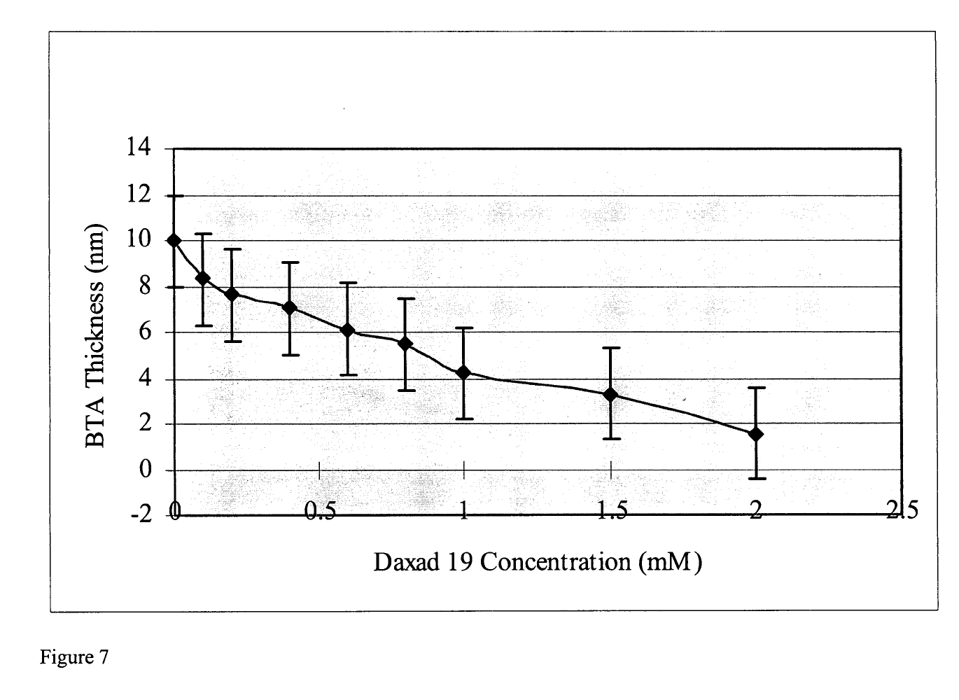

A set of solutions with similar chemical compositions as described in the above examples were prepared. The solutions contain various amount of polyelectrolyte Daxad 19. Daxad 19 is a representative anionic polyelectrolyte that contains sulfonate groups on napthylene aromatic ring. As shown in FIG. 6, the presence of such an anionic polyelectrolyte reduces the BTA film thickness as well as static etch rate (FIG. 7). It is apparent that the presence of such negatively charged polymer leads to a thinner and denser passivating film.

### Example 5

### CMP Solutions with Colloidal Particles

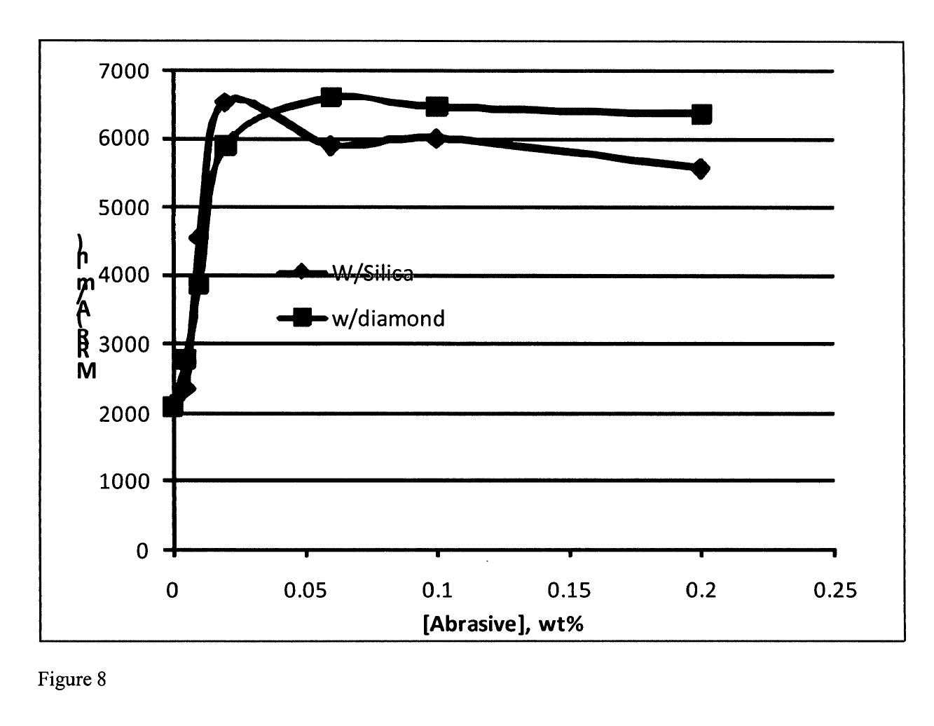

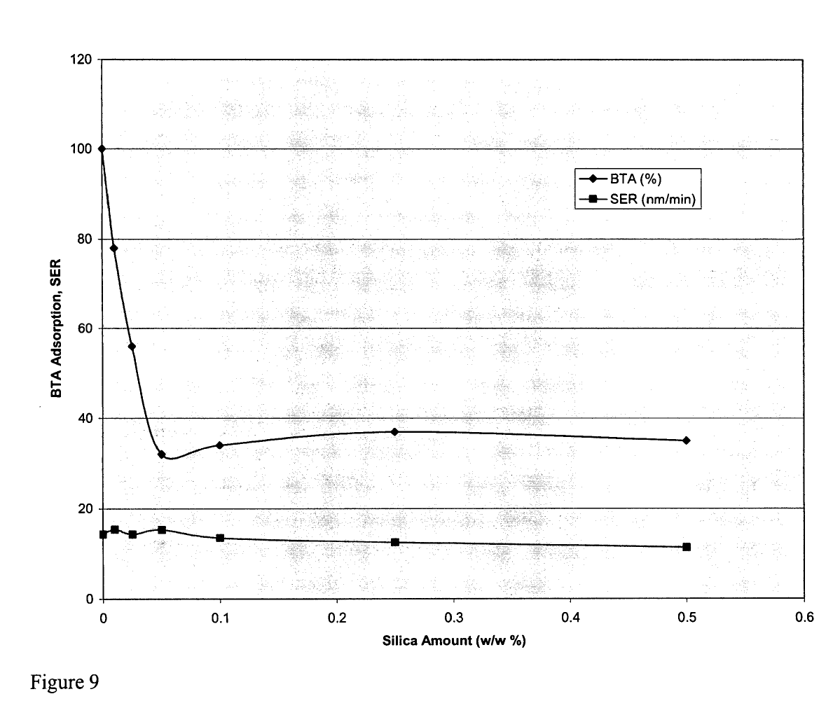

A set of solutions with similar chemical compositions as described in the Example 1 were prepared. The solutions were then added with various amount of colloidal silica. The most significant impact of these added colloidal particles is on the removal rate. It was totally unexpected that such a small amount of colloidal silica could make such a drastic effect on removal rate. As matter of fact the removal rate increase is similar to that of diamond particles (FIG. 8). In another word, the hardness of the abrasive particles are totally equalized or ignored in this set of polishing. This is only consistent with the fact that the abrasive particles have incorporated into the passivation film and have become an integral part of the passivation film. The integration of such particles significantly weakened the passivating film which leads to higher removal rate. As shown in FIG. 9 that the total amount of BTA adsorbed onto the copper powders is significantly reduced. The static etch rate however has maintained about the same. This is consistent with the fact that the abrasive particles the incorporation of the abrasive particles have squeezed the BTA molecules out of the film. However, the passivation efficiency is still just as good. An EDX examination of the film confirmed that the silica is present in the passivating film.

### Example 6

The incorporation of colloidal particles into the passivation film not only impacts the CMP performance of a slurry by increasing its removal rate but also can improve its planarization efficiency.

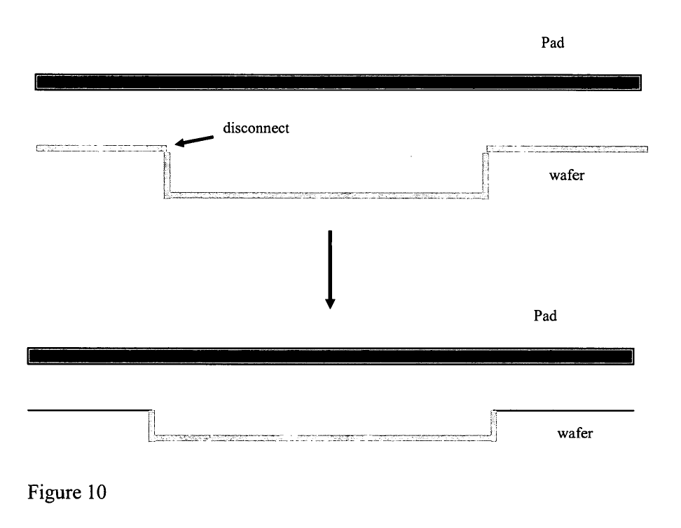

As a background, the Kaufman model for step height reduction requires is illustrated in FIG. 10. In this model, an effective passivating film is needed to vertically block the chemical transport across the film. This will in effect prevent the copper surface from direct contact with the attacking chemicals in solution and dissolved ions from leaving the copper surface. As the film on the protruded areas is more often removed from the surface by the rubbing actions of a pad than those in the recessed areas, a step height reduction is achieved over time.

It is important to point out that the passivation film needs to have moderate lateral adhesion. If such a lateral adhesion is too weak, the passivation film will be too porous and too weak to withstand any mechanical forces. It can not be too strong either. If the lateral adhesion is too strong, the breakage at the corners of the trench will not be efficient.

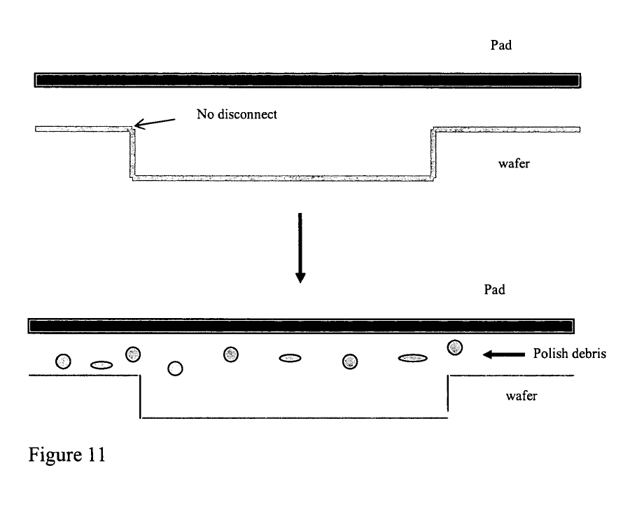

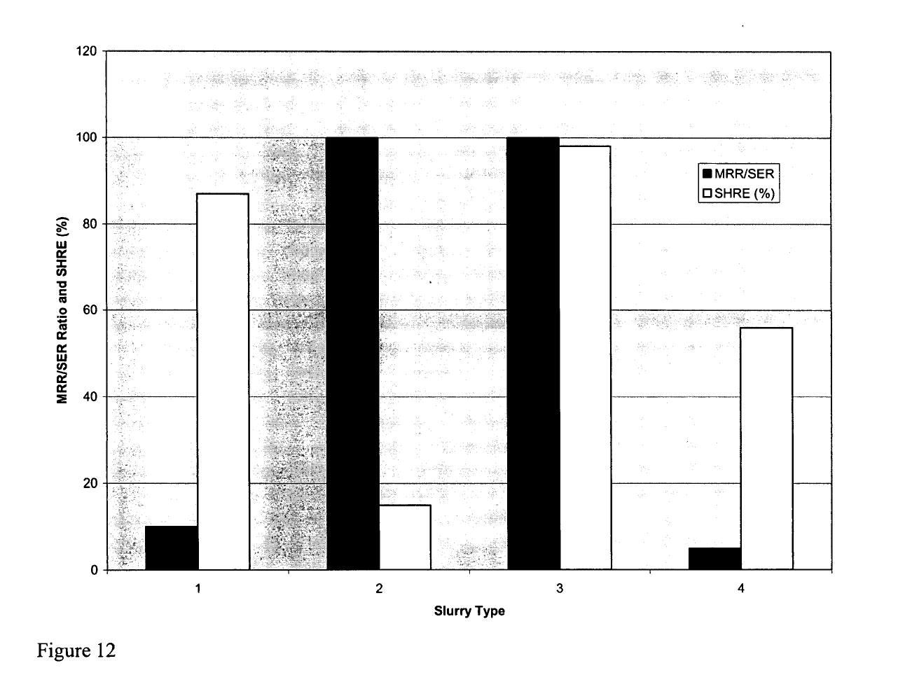

Under such a circumstance, the entire passivation film may delaminate across the trench as shown in FIG. 11. The step height reduction efficiency will be low. In other words, a slurry that gives high removal rate and low static etch rate does not always yield high step height reduction efficiency as shown in FIG. 12.

It is generally believed that a higher removal rate and lower static etch rate will ensure a high step height reduction efficiency. This is true for a BTA based slurry (Type 1). However, for a thiol based slurry (Type 2) with very high removal rate and extremely low static etch rate, the step height reduction is very low. It is hypothesized that a delamination mechanism may have dominated the film removal. The Type 3 slurry is essentially the same as Type 2 except it incorporated colloidal particles into the slurry and possibly in the passivation film. The step height reduction efficiency is increased. The Type 4 is the same as Type 2 except the incorporation of chloride ions. Both the static etch rate and step height reduction efficiency are increased.

To prevent such delamination, the passivation film must be optimized. The incorporation of colloidal particles, polyelectrolytes, or other ionic species is an effective option.

### Example 7

### Effect of Colloidal Particles on Step Height Reduction Efficiency

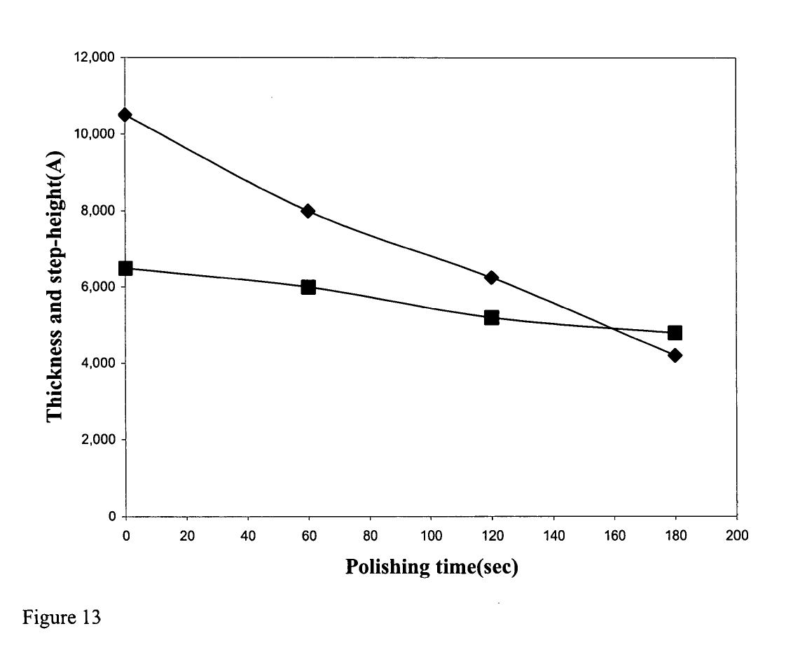

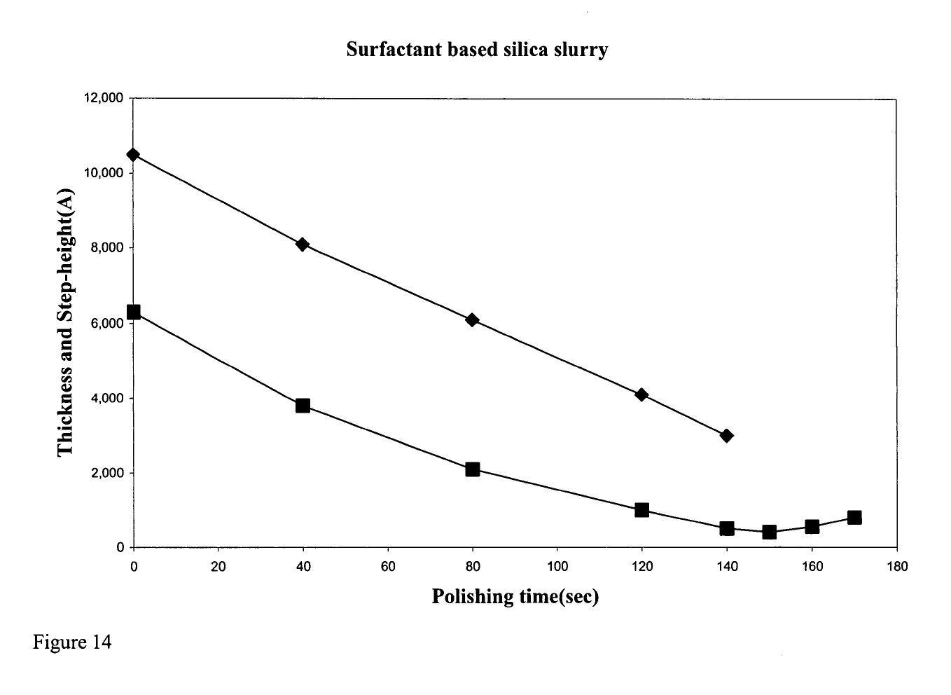

The principles described in Example 6 can also be extended to weaker passivation films. As shown in FIG. 13, the step height reduction efficiency is fairly low for a surfactant based abrasive free solution. This is a direct result of a weak passivation film. The shear force of slurry flow during polishing is most likely strong enough to sweep away the passivation film in both recessed and protruded areas. In another word, there are no breaking points at the corners of the trenches. The delamination mechanism dominates the material removal. In this case, both static etch rate and removal rate can be low. The addition of colloidal particles, the step height reduction efficiency is significantly increased (FIG. 14).

### Example 8

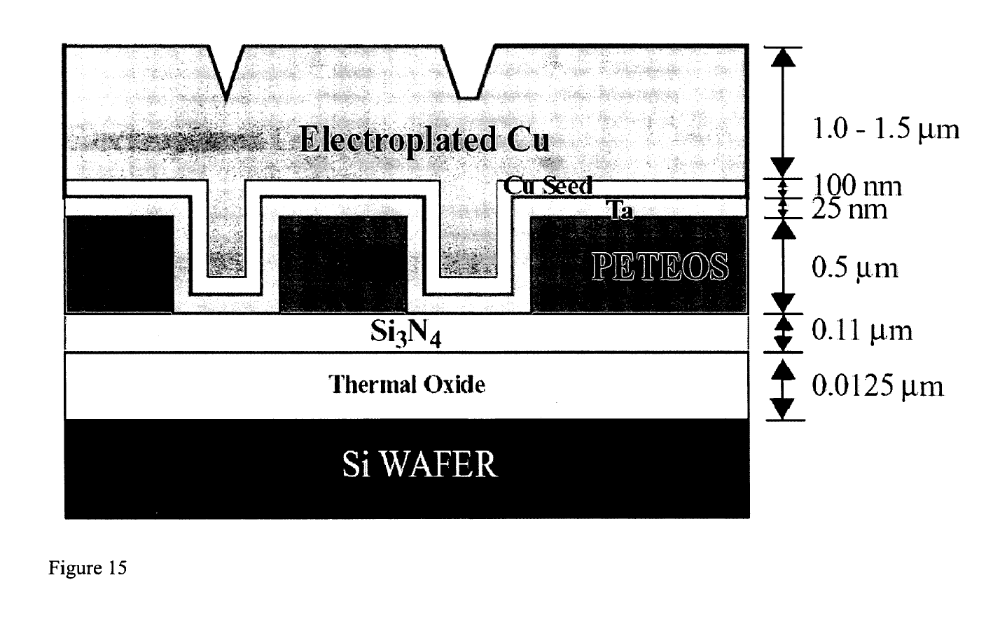

The basic principles described in Example 7 can also be extended to situation in which the material removal rate in the protruded areas could be different from those in the recessed areas. More specifically, as shown in FIG. 15, when the copper polishing reaches its seed layer, the passivating film covers two types of copper materials—the electroplated (EP) in the trenches and physical vapor deposited (PVD) on the top.

Due to the fact that PVD copper contains significantly less chloride ions than that in EP copper, the passivation film thickness and strength could be quite difference at the corners of the trenches. The later usually leads to a high material removal rate in the trench or EP copper which, in turn, gives high dishing values. To prevent such high dishing from occurring, an addition of chloride ions into the slurry to bring the chloride ion concentrations to a level that could eliminate the small differences between the two types of coppers. Another approach may include the incorporation of colloidal particles that could increase the material removal rate of the copper in the protruded areas.

### Example 9

The basic principles illustrated in Examples 2-8 can be extended to a situation in which a significant amount of copper has to be removed from the substrate. More specifically, the slurry must be capable of removing copper at a significantly high rate. Some representative applications of this slurry include the preparation of Trans-Silicon-Via (TSV), Mechanical Electrical Machines (MEMS), recycled circuit boards, and other metal interconnects among large structures. The structures in these applications are usually in the order of tens of micrometers. The amount of copper to be removed is also in the order of tens of micrometers in thinness. In order for the process to be economically viable, the removal rate of such process should be in the range of 2-5 micrometers per minute which is about ten times higher than that used in normal copper interconnect preparation. In order to achieve such a high removal rate, a slurry must be formulated to be able to form a thin and easy-to remove-film on the substrate. Based on the basic principles illustrated in examples 2-8, the film-forming agent should be selected from a group of molecules that allow the intercalation of ionic species such as chloride and colloidal particles such as silica. One such example is benzimidazole. Unlike benzotriazole, benzimidazole is a weaker passivating agent which allows the formation of a more porous film in the presence of compatible ionic species and colloidal particles. As matter of fact an entire class of such weak passivating agents can be used for this application. For example, all alkyl and aryl derivatives of benzimidazoles can be classified into this category. More broadly, any nitrogen containing compounds that can form a thin film on copper surface that is weaker than benzotriazole can be grouped into this class. The definition of a weaker film can be described as easier to remove under the same mechanical conditions such as downforce, rotational speed, pad hardness, and a combination of other abrasive forces including abrasive particles. In addition to the requirement described above on these important ingredients, the key for a high removal rate slurry is the combination of optimized concentrations. As an example, a combination of 5-10 millimolar benzimidazole, 50-300 ppm of potassium chloride, 1-3% of hydrogen peroxide, 1-2% glycine, 0.01-0.1% Triton X-100, 0.01-0.02% polyethlenimine (molecular weight 2000), and 0.1-1% colloidal silica yielded a slurry that is capable of removing 2-3 micrometers of copper film from a substrate under mild polishing condition (3 psi down force and 75 rpm rotational speed). The polishing also yield relatively low dishing and erosion as shown in Table 1.

Having thus described in detail various embodiments of the present invention, it is to be understood that the invention defined by the above paragraphs is not to be limited to particular details set forth in the above description as many apparent variations thereof are possible without departing from the spirit or scope of the present invention.

### REFERENCES

1. Steigerwald J. M, Murarka S. P, and Gatmann R. J. Chemical Mechanical Planarization of Microelectronic Materials. John Wiley & Sons, New York; 1996.
2. Hariharaputhiran M, Zhang J, Ramarajan S, Keleher J, Li Y, and Babu S V. Hydroxyl radical formation in H₂O₂-Amino acid mixtures and chemical mechanical polishing of copper. J. Electrochem. Society 2000; 147(10): 3820-3826.
3. Luo Q, Campbell D R, and Babu S V. Stabilization of alumina slurry for chemical-mechanical polishing of copper. Langmuir 1996; 12: 3563.
4. Luo Q, Campbell D R, Babu S V, Proceedings of the 1st International VMIC Specialty Conference on CMP Planarization, p. 145, Santa Clara, Calif., February 1996.
5. Wang M T, Tsai M S, Liu C, Tseng W T, Chang T C, Chen L J, Chen M C. Effects of corrosion environments on the surface finishing of copper chemical mechanical polishing. Thin Solid Films 1997; 518: 308.
6. Walsh J, Dhariwal H, Gutierrez A, Finneti P, Muryn C, Brookes N, Oldman R, Thomton G. Probing molecular orientation in corrosion inhibition via a NEXAFS study of benzotriazole and related molecules on Cu(100). Surf Sci. 1998; 415: 423.
7. Notoya T, Poling G. Corrosion (Houston) 1976; 32: 216.
8. Brusic V, Frisch M A, Eldridge B N, Novak F P, Kaufman F B, Ruch B F, Frankel G S. Copper corrosion with and without inhibitors. J. Electrochem. Soc. 1991; 138: 2253.
9. Tommesani L, Brunoro G, Frignani A, Monticelli C, Dal Colle M. On the protective action of 1,2,3-benzotriazole derivative films against copper corrosion. Corros. Sci. 1997; 39: 1221.
10. Carpio R, Farkas J, Jairath R. Initial study on copper CMP slurry chemistries. Thin Solid Films 1995; 266: 238-244.
11. Thierry D, Leygraf C. Simultaneous raman spectroscopy and electrochemical studies of corrosion inhibiting molecules on copper. J. Electrochem. Soc. 1985; 132: 1009.
12. Rubim J, Gutz I G R, Sala O, Orville-Thomas W J. Surface enhanced Raman spectra of benzotriazole adsorbed on a copper electrode. J. Mol. Struct. 1983; 100: 571.
13. Cohen S L, Brusic V A, Kaufman F B, Frankel G S, Motakef S, Rush B. X-ray photoelectron spectroscopy and ellipsometry studies of the electrochemically controlled adsorption of benzotriazole on copper surfaces. J. Vac. Sci. Technology. 1990; A 8 (3): 2417.
14. Poling G W, Reflection infra-red studies of films formed by benzotriazole on Cu, Corrosion Sci. 1970; 10, 5, 359.
15. Chadwick D, Hashemi T. Adsorbed corrosion inhibitors studied by electron spectroscopy: Benzotriazole on copper and copper alloys. Corrosion Sci. 1978; 18: 359.
16. Fox P. G, Lewis G, Boden P J. Some chemical aspects of the corrosion inhibition of copper by benztriazole. Corrosion Sci. 1979; 19: 457.
17. Tamilmani S, Huang W, Raghavan S, Small R. Potential-pH diagrams of interest to chemical mechanical planarization of copper. J. Electrochem. Soc. 2002; 149 (12): G638-G642.
18. Hang Y K, Eom D H, Park J G. Electrochem. Soc. Meeting, San Fransisco, Calif., Sep. 2-7; 2001.
19. Deshpande S, Kuiry S C, Klimov M, Obeng Y, Seal S. Chemical Mechanical Planarization of Copper: Role of Oxidants and Inhibitors. J. Electrochem. Soc. 2004; 151: G788.
20. Luo Q, Babu S V. Dishing Effects during Chemical Mechanical Polishing of Copper in Acidic Media. J. Electrochem. Soc. 2000; 147 (12): 4639-4644.
21. Tsai T-H, Yen S-C. Localized corrosion effects and modifications of acidic and alkaline slurries on copper chemical mechanical polishing. Applied Surface Science 2003; 210 (3-4): 190.
22. Steigerwald J M, Murarka S P, Gutmann R J, Duquette D J. Chemical processes in the chemical mechanical polishing of copper. Mater. Chem. Phys. 1995; 41: 217.
23. Notoya T, Satake T M, Ohtsuka T, Yashiro H, Sato M, Yamauchi T, Schweinsberg D P, Paper 076 (https://www.umist.ac.uk/corrosion/JCSE), International Symposium on Corrosion Science in the 21st Century, UMIST, Manchester, U.K., Jul. 6-11, 2003.
24. Surya Sekhar M, Ramanathan S. Characterization of copper chemical mechanical polishing (CMP) in nitric acid-hydrazine based slurry for microelectronic fabrication. Thin Solid Films 2006; 504 (1-2): 227-230.
25. Du T, Luo Y, Desai V. The combinatorial effect of complexing agent and inhibitor on chemical-mechanical planarization of copper. Microelectronic Engineering 2004; 71 (1): 90-97.
26. Hu T C, Chiu S Y, Dai B T, Tsai M S, Tung I-C, Feng M S. Nitric acid-based slurry with citric acid as an inhibitor for copper chemical mechanical polishing. Materials Chemistry and Physics 1999; 61 (2): 169-171.
27. Lee W-J. Inhibiting effects of imidazole on copper corrosion in 1 M HNO₃ solution. Mat. Sci. Eng. 2003; AC348: 217.
28. Hong Y, Patri U B, Ramakrishnan S, Roy D, Babu S V. Utility of dodecyl sulfate surfactants as dissolution inhibitors in chemical mechanical planarization of copper. J. Material. Res. Soc. 2005; 20 (12): 3413.
29. Holberg L, Jonseen B, Kronberg B, Lindman B. Surfactants and Polymers in Aqueous Solution, 2nd ed. Wiley; 2003.
30. Govindaswamy S, Cheemalapati K, Li Y. Evaluation of Surfactant as Corrosion Inhibitor in Copper Chemical Mechanical Planarization, Unpublished results, 2006.
31. Zhao J, Bundi D, Cheemalapati K, Duvvuru V, Li Y. A Non-BTA Based Novel Post CMP Clean Solution. CMP-MIC 2005.

What is claimed is:

1. A copper chemical mechanical planarization slurry composition which comprises of a complexing agent, an oxidizer, an abrasive and a passivating agent.

2. The composition of claim 1, wherein:
the complexing agent is selected from the group consisting of glycine, ammonium citrate, ammonium phosphate, ammonium acetate, ammonium thiocyanate, 2,4-pentadione and combinations thereof;
the oxidizer is hydrogen peroxide, ammonium persulfate, potassium iodate, potassium permanganate, ferric nitrate, cerium (IV) compounds, ceric nitrate, ceric ammonium nitrate, bromates, chlorates, chromates, and iodic acid, and mixtures thereof;
the abrasive is selected from the group consisting of colloidal particles, polyelectrolytes, an ionic compound and combinations thereof; and
the passivating agent is benzotriazole.

3. The composition of claim 2, wherein
the colloidal particles are selected from the group consisting of silica, alumina, titania, ceria, zirconia, and diamond;
the polyelectrolytes are selected from the group consisting of polystyrene sulfonate
(PSS), poly(acrylic acid) (PAA), Lignosulfonates, Nafion, polyethylene amine, poly(2-acrylamido-2-methyl-1-propanesulfonic acid), naphthalene sulfonate formaldehyde condensate and polyaniline; and
the ionic species are selected from the group consisting of chloride, bromide, iodide, fluoride, isocyanides, acetates, sulfate, and persulfate.

4. The composition of claim 3, wherein the complexing agent is glycine, the oxidizer is hydrogen peroxide and the passivating agent is benzotriazole.

5. The composition of claim 4, wherein the abrasive agent is chloride.

6. The composition of claim 4, wherein the abrasive agent is a naphthalene sulfonate formaldehyde condensate.

7. The composition of claim 4, wherein the abrasive agent is silica.

8. A method of chemical mechanical planarization of a copper conductive structure which comprises administering the composition of claim 1 during the planarization process.

9. The composition of claim 8, wherein:
the complexing agent is selected from the group consisting of glycine, ammonium citrate, ammonium phosphate, ammonium acetate, ammonium thiocyanate, 2,4-pentadione and combinations thereof;
the oxidizer is hydrogen peroxide, ammonium persulfate, potassium iodate, potassium permanganate, ferric nitrate, cerium (IV) compounds, ceric nitrate, ceric ammonium nitrate, bromates, chlorates, chromates, and iodic acid, and mixtures thereof;
the abrasive is selected from the group consisting of colloidal particles, polyelectrolytes, an ionic compound and combinations thereof; and
the passivating agent is benzotriazole.

10. The composition of claim 9, wherein
the colloidal particles are selected from the group consisting of silica, alumina, titania, ceria, zirconia, and diamond;
the polyelectrolytes are selected from the group consisting of polystyrene sulfonate (PSS), poly(acrylic acid) (PAA), Lignosulfonates, Nafion, polyethylene amine, poly(2-acrylamido-2-methyl-1-propanesulfonic acid), naphthalene sulfonate formaldehyde condensate and polyaniline; and
the ionic species are selected from the group consisting of chloride, bromide, iodide, fluoride, isocyanides, acetates, sulfate, and persulfate.

11. The composition of claim 10, wherein the complexing agent is glycine, the oxidizer is hydrogen peroxide and the passivating agent is benzotriazole.

12. The composition of claim 11, wherein the abrasive agent is chloride.

13. The composition of claim 11, wherein the abrasive agent is a naphthalene sulfonate formaldehyde condensate.

14. The composition of claim 11, wherein the abrasive agent is silica.
